(19) United States
(12) Patent Application Publication
(10) Pub. No.: US 2011/0260764 A1
(43) Pub. Date: Oct. 27, 2011

(54) SEMICONDUCTOR INTEGRATED CIRCUIT, METHOD FOR DESIGNING SEMICONDUCTOR INTEGRATED CIRCUIT, AND COMPUTER READABLE RECORDING MEDIUM

(75) Inventors: Takeshi KITAHARA, Kawasaki-Shi (JP); Takashi ISHIOKA, Kawasaki-Shi (JP); Toshiaki SHIRAI, Tokyo (JP)

(73) Assignee: KABUSHIKI KAISHA TOSHIBA, Tokyo (JP)

(21) Appl. No.: 12/954,530

(22) Filed: Nov. 24, 2010

(30) Foreign Application Priority Data
Apr. 23, 2010 (JP) 2010-99822

(51) Int. Cl. H03K 3/289; H03K 3/00; G06F 17/50

(52) U.S. Cl. 327/202; 716/134; 327/199

(57) ABSTRACT

A method for designing a semiconductor integrated circuit according to an embodiment includes: placing standard flip-flop circuits and low power-consumption flip-flop circuits; grouping the placed flip-flop circuits into clusters by using an evaluation function having indices including cell types; assigning a first clock buffer to each cluster formed only by standard flip-flop circuits; assigning a second clock buffer to each cluster including low power-consumption flip-flop circuits, the second clock buffer having a larger size than the first clock buffer; and performing clock wiring.

### CROSS REFERENCE TO RELATED APPLICATION

This application is based upon and claims benefit of priority from the Japanese Patent Application No. 2010-99822, filed on Apr. 23, 2010, the entire contents of which are incorporated herein by reference.

### FIELD

Embodiments described herein relate generally to a semiconductor integrated circuit, a method for designing a semiconductor integrated circuit, and a computer readable recording medium.

### BACKGROUND

In the layout design of LSI (Large Scale Integrated) circuits, a clock circuit is formed by a circuit of a tree-type structure, so as to counter clock skews (differences in clock signal delay time among flip-flops to which a clock signal is supplied).

In a LSI, low power-consumption flip-flops having smaller internal clock buffers than those in regular flip-flops are used to reduce power consumptions. In such low power-consumption flip-flops, the delay time of each flip-flop greatly depends on the clock input waveform (clock slews). More specifically, when the clock input waveform becomes rounder, the delay times of the flip-flops become longer than those of regular flip-flops.

When such low power-consumption flip-flops are used, the upper limit of clock slews is set, and a clock-tree synthesis (CTS) operation is performed, so as not to increase delay times. As a result, the stews of regular flip-flops become sharper than necessary. Therefore, clock buffers having large driving forces are inserted, which leads to an increase of the power consumption by the clock three.

Where the upper limit of clock slews of regular flip-flops is set in a CTS operation, the delay times of the above described low power-consumption flip-flops become longer. To satisfy timing constraints, low power-consumption flip-flops are not often used, and reducing the power consumption by a LSI circuit becomes difficult.

### BRIEF DESCRIPTION OF THE DRAWINGS

FIGS. 1(a) and 1(b) are circuit diagrams showing an example of a flip-flop circuit;

FIG. 2 is a graph showing the relationship between the clock slew of each flip-flop circuit and the delay time;

FIG. 3 is a diagram schematically showing the structure of an apparatus for designing a semiconductor integrated circuit according to an embodiment;

FIG. 4 is a flowchart for explaining a method for designing a semiconductor integrated circuit according to the embodiment;

FIGS. 5(a) and 5(b) are diagrams illustrating an example of a CTS operation;

FIG. 6 is a diagram illustrating an example of a CTS operation;

FIGS. 7(a) and 7(b) are diagrams illustrating an example of a CTS operation;

FIG. 8 is a circuit diagram showing an example of a low power-consumption flip-flop circuit; and

FIG. 9 is a circuit diagram showing an example of a low power-consumption flip-flop circuit.

### DETAILED DESCRIPTION

According to this embodiment, a method for designing a semiconductor integrated circuit includes: placing first flip-flop circuits and second flip-flop circuits each having a larger amount of delay change than the first flip-flop circuits with respect to a change of a clock signal waveform; grouping the first flip-flop circuits and the second flip-flop circuits into clusters by using an evaluation function; assigning a first clock buffer to a first cluster that is formed by the first flip-flop circuits; assigning a second clock buffer to a second cluster that includes the second flip-flop circuits, the second clock buffer having a larger size than the first clock buffer; and performing clock wiring in such a manner that the output of the first clock buffer is supplied to the first flip-flop circuits forming the first cluster, and the output of the second clock buffer is supplied to the second flip-flop circuits forming the second cluster. The evaluation function has indices that include the coordinates of each flip-flop circuit, the input slew constraints, the clock input capacity, and the cell types that indicate whether the flip-flop circuits are the first flip-flop circuits or the second flip-flop circuits.

The following is a description of an embodiment of the present invention, with reference to the accompanying drawings.

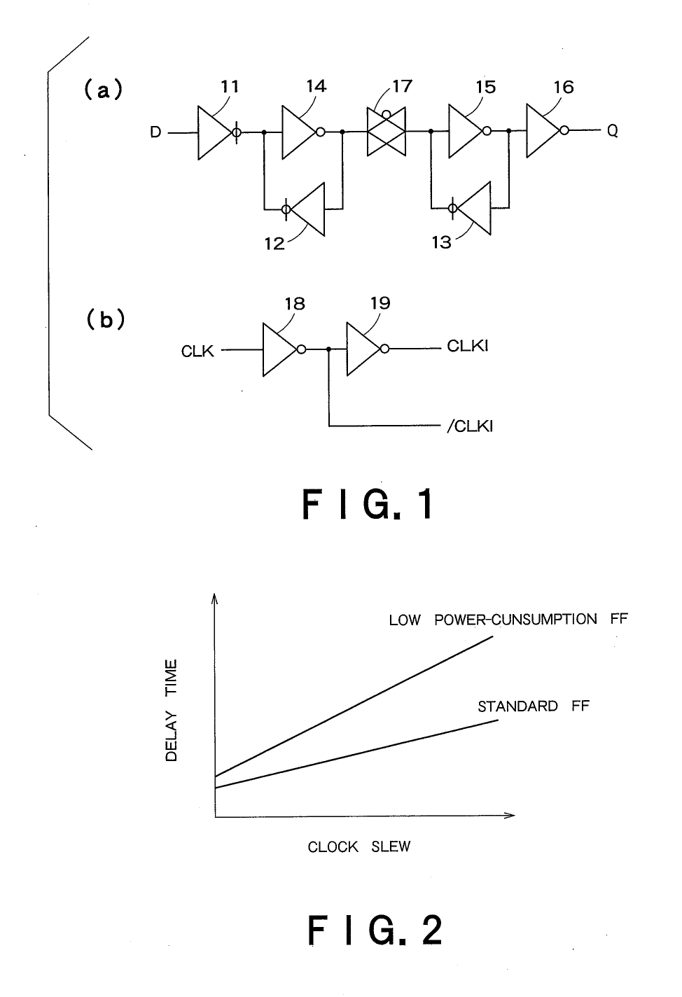

FIGS. 1(a) and 1(b) illustrate an example structure of a flip-flop circuit. FIG. 1(a) illustrates a signal transmission circuit of the flip-flop circuit. FIG. 1(b) illustrates a clock supply circuit of the flip-flop circuit. The signal transmission circuit includes clocked inverters 11 through 13, inverters 14 through 16, and a transmission gate 17.

A data signal D is input to the clocked inverter 11. The output of the clocked inverter 11 is connected to the input of the inverter 14 and the output of the clocked inverter 12. The output of the inverter 14 and the input of the clocked inverter 12 are connected to the input of the transmission gate 17. The output of the transmission gate 17 is connected to the input of the inverter 15 and the output of the clocked inverter 13. The output of the inverter 15 and the input of the clocked inverter 13 are connected to the input of the inverter 16. The inverter 16 outputs an output signal Q.

The clock supply circuit of the flip-flop circuit includes inverters 18 and 19. The input of the inverter 18 is connected to the supply node of a clock signal CLK, and the input of the inverter 19 is connected to the output of the inverter 18. An internal clock signal CLKI is supplied from the output of the inverter 19, and an internal clock inverted signal/CLKI is supplied from the output of the inverter 18.

The clocked inverter 12 operates as an inverter when the internal clock signal CLKI is at the high level. The output of the clocked inverter 12 is in a high impedance state when the internal clock signal CLKI is at the low level, and separates the input and the output from each other. The clocked inverters 11 and 13 operate as inverters when the internal clock signal CLKI is at the low level. The outputs of the clocked inverters 11 and 13 are in a high impedance state when the internal clock signal CLKI is at the high level, and separates the input and the output from each other. The transmission gate 17 allows signals to pass when the internal clock signal CLKI is at the high level, but does not allow signals to pass when the internal clock signal CLKI is at the low level.

When the clock signal CLK is at the low level, the data signal D is input to the inverter 14, after passing through the clocked inverter 11. Since the internal clock signal CLKI is at the low level, the transmission gate 17 and the clocked inverter 12 are closed, and the input signal is blocked.

When the clock signal CLK is switched from the low level to the high level, the clocked inverter 11 is closed, and the transmission gate 17 and the clocked inverter 12 are opened. In other words, as soon as the clock signal CLK is switched, the data signal D is latched by the inverter 14 and the clocked inverter 12, and is output through the transmission gate 17 and the inverters 15 and 16.

When the clock signal CLK is switched from the high level to the low level, the transmission gate 17 is closed, and the clocked inverter 13 is opened. As a result, the signal passing through the transmission gate 17 is latched by the inverter 15 and the clocked inverter 13, and is output from the inverter 16. This situation lasts until the transmission gate 17 is opened and a signal of a different level is input.

In such a flip-flop circuit, the power consumption can be made smaller by reducing the sizes of the inverters 18 and 19 of the clock supply circuit illustrated in FIG. 1(b). In this embodiment, flip-flop circuits that have inverters 18 and 19 of various sizes are provided in a semiconductor integrated circuit. In the following description, flip-flop circuits that include inverters 18 and 19 of large sizes and have high operating speeds will be called standard flip-flop circuits, and flip-flop circuits that include inverters 18 and 19 of small sizes, consume less electricity than the standard flip-flop circuits, and have lower operating speeds than the standard flip-flop circuits will be called low power-consumption flip-flop circuits.

FIG. 2 illustrates an example of the relationship between the clock slew and the delay time in each of the standard flip-flop circuits (standard FF) and the low power-consumption flip-flop circuits (low power-consumption FF). As shown in FIG. 2, the low power-consumption flip-flop circuits are more sensitive to clock slews than the standard flip-flop circuits are. In other words, each low power-consumption flip-flop circuit has a larger delay increase with respect to a change in waveform (waveform rounding) of a clock signal than that of each standard flip-flop circuit.

This embodiment concerns designing of a semiconductor integrated circuit with the use of the above described standard flip-flop circuits and low power-consumption flip-flop circuits.

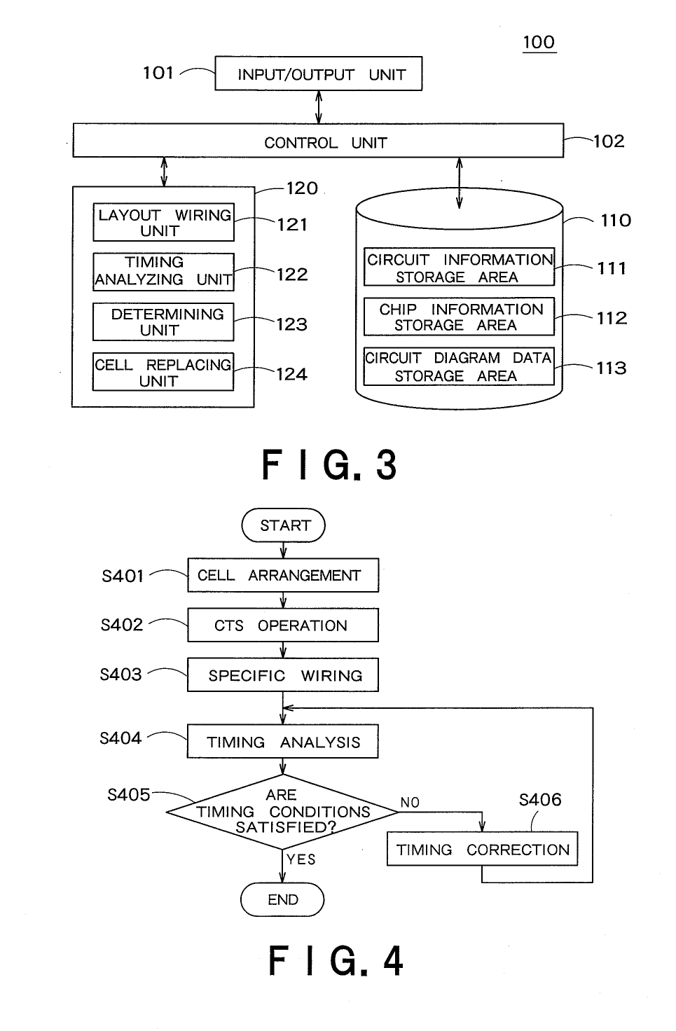

FIG. 3 schematically illustrates the structure of an apparatus for designing a semiconductor integrated circuit according to this embodiment. The designing apparatus 100 includes an input/output unit 101, a control unit 102, a storage unit 110, and an operating unit 120. The input/output unit 101 inputs and outputs data. The control unit 102 performs data transfer control among the input/output unit 101, the storage unit 110, and the operating unit 120.

The storage unit 110 includes a circuit information storage area 111, a chip information storage area 112, and a circuit diagram data storage area 113.

The circuit information storage area 111 stores the information about devices such as flip-flops placed in the chip, and circuit design information such as connection information about each device (a netlist). The flip-flops include the above described standard flip-flop circuits and the low power-consumption flip-flop circuits.

The chip information storage area 112 stores information about the size of the chip in which devices are to be placed, for example. The diagram data storage area 113 stores circuit diagram data that is the information about the chip in which the devices are placed.

The operating unit 120 includes a layout wiring unit 121, a timing analyzing unit 122, a determining unit 123, and a cell replacing unit 124.

The layout wiring unit 121 places devices, based on the circuit design information and the chip information. The layout wiring unit 121 inserts clock buffers in a clock wiring network, and performs a CTS (clock-tree synthesis) operation to obtain a layout by adjusting the load balance in a tree-like fashion. In the CTS operation, a clustering operation (grouping) is performed to create clusters (groups) each containing adjacent flip-flop circuits. After that, a clock buffer is inserted for (assigned to) each cluster. In the clustering operation, clusters are created in such a manner that the following evaluation function f is minimized:

f (the cell type of each flip-flop, the coordinates of each flip-flop, the clock input terminal capacity of each flip-flop, the cell list of clock buffers that can be used, the restriction on the maximum input slew with respect to the clock input terminal of each flip-flop, the restriction on the maximum fan-out of the clock buffers, and the restriction on the maximum load capacity of the clusters)

The cell type of a flip-flop indicates whether the flip-flop is a standard flip-flop circuit or a low power-consumption flip-flop circuit.

The layout wiring unit 121 performs the wiring of data lines for transmitting data signals after performing the wiring of clock lines for transmitting clock signals, to generate circuit diagram data. The layout wiring unit 121 then writes the circuit diagram data into the circuit diagram data storage area 113.

The timing analyzing unit 122 carries out a predetermined high-precision timing analysis of the circuit diagram data stored in the circuit diagram data storage area 113. The timing analysis is carried out by measuring the clock delay time of the clock tree wiring formed in the CTS operation, the delay time in the data path, and the operation speed of the semiconductor circuit.

The determining unit 123 determines whether the result of the analysis carried out by the timing analyzing unit 122 satisfies predetermined timing conditions.

The cell replacing unit 124 performs a timing correction (IPO: in place optimization) on the circuit diagram data. For example, the cell replacing unit 124 replaces the provided clock buffers with clock buffers having larger driving capacities according to design constraints.

Referring now to the flowchart shown in FIG. 4, a method for designing a semiconductor integrated circuit with the use of the designing apparatus 100 is described.

(Step S401) The layout wiring unit 121 logically combines and places standard flip-flop circuits and low power-consumption flip-flop circuits, based on the circuit design information and chip information.

(Step S402) The layout wiring unit 121 performs a CTS operation. Through the CTS operation, a clustering operation, clock-tree wiring, and a clock buffer insertion are performed.

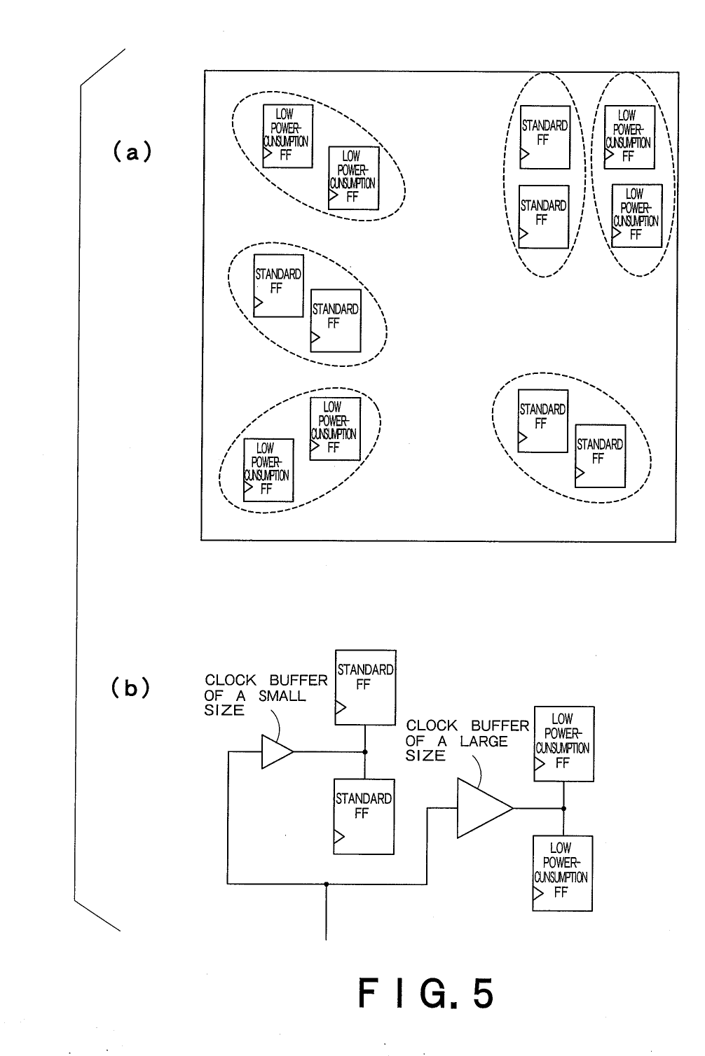

In the clustering operation, the above described evaluation function f is used, and adjacent flip-flop circuits are combined to form a cluster. The indices in the evaluation function f contain the cell type of each flip-flop. With this placement, flip-flop circuits of the same type are easily contained in the same cluster, as shown in FIG. 5(a).

As shown in FIG. 5(b), a clock buffer of a small size is inserted in each cluster formed only by standard flip-flop circuits, and a clock buffer of a large size is inserted in each cluster formed only by low power-consumption flip-flop circuits. A clock buffer of a large size is inserted in each cluster that includes both a low power-consumption flip-flop circuit and a standard flip-flop circuit. As described in conjunction with FIG. 2, each low power-consumption flip-flop circuit is sensitive to clock slews, and a clock signal that is output from a clock buffer having a large driving force needs to be supplied to each low power-consumption flip-flop circuit.

(Step S403) The layout wiring unit 121 performs specific wiring, and performs data signal wiring. In this manner, circuit diagram data is created. In this step, general wiring, instead of specific wiring, may be performed to create circuit diagram data.

(Step S404) The timing analyzing unit 122 carries out a timing analysis on the circuit diagram data.

(Step S405) The determining unit 123 determines whether the result of the timing analysis satisfies predetermined timing conditions. In a case where the result satisfies the predetermined timing conditions, the operation comes to an end. In a case where the result does not satisfy the predetermined timing conditions, the operation moves on to step S406.

(Step S406) The cell replacing unit 124 performs a timing correction on the circuit diagram data, and the operation then returns to step S404.

If a clustering operation is performed with the types of the flip-flops being not taken into consideration, the number of clusters each containing both a standard flip-flop circuit and a low power-consumption flip-flop circuit becomes larger. Since a clock buffer having a large driving force is inserted in each of such clusters, the power consumption by the clock tree becomes larger.

In this embodiment, on the other hand, a clustering operation is performed with the types of flip-flops being taken into consideration. Accordingly, clusters each containing only standard flip-flop circuits can be more easily created. Clock buffers having small driving forces can be inserted in such clusters. Accordingly, the power consumption by the clock tree can be reduced, and the power consumption by the entire semiconductor integrated circuit can also be reduced.

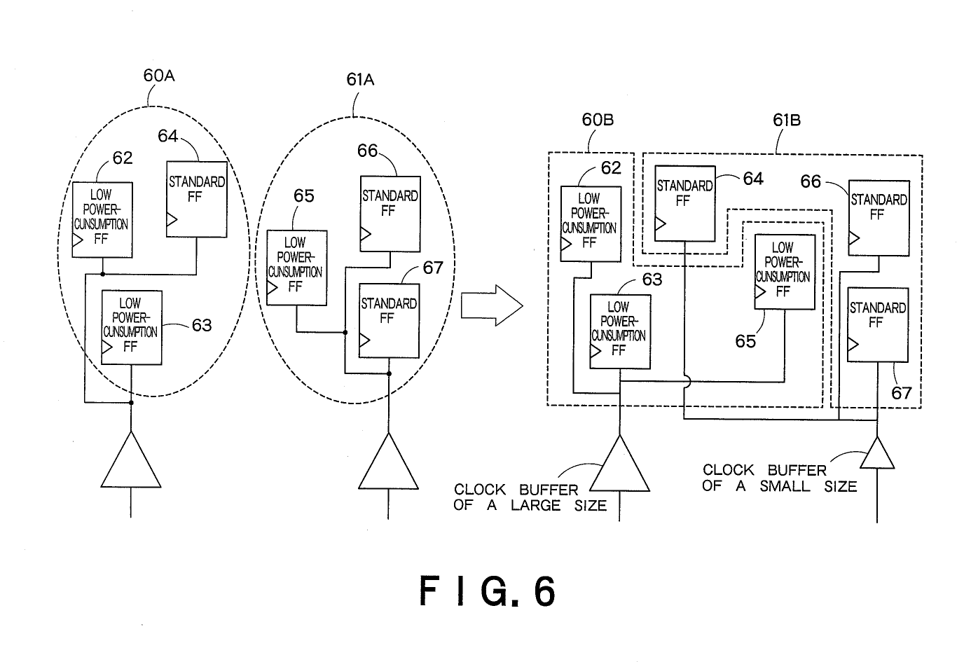

As shown in FIG. 6, the layout wiring unit 121 may compare adjacent clusters with each another, and correct the clusters so as to form a cluster containing only standard flip-flop circuits in the clustering operation. In this example, low power-consumption flip-flop circuits 62 and 63 of a cluster 60A and a low power-consumption flip-flop circuit 65 of a cluster 61A form a new cluster 60B, and a standard flip-flop circuit 64 of the cluster 60A and standard flip-flop circuits 66 and 67 of the cluster 61A form a new cluster 61B.

With this placement, the number of clusters containing only standard flip-flop circuits becomes larger, and the number of portions in which clock buffers having small driving forces are inserted also becomes larger. Accordingly, the power consumption by the clock tree can be reduced further. A cluster correction is performed only when a value of the above described evaluation function f is equal to or smaller than a predetermined threshold value, and the positions of the placed flip-flop circuits are not to be changed.

In the example illustrated in FIG. 6, the low power-consumption flip-flop circuit 65 of the cluster 61A is included in the cluster 60A, and only the standard flip-flop circuits 66 and 67 may form one cluster.

Although two clusters are restructured in the example illustrated in FIG. 6, three or more clusters may be restructured.

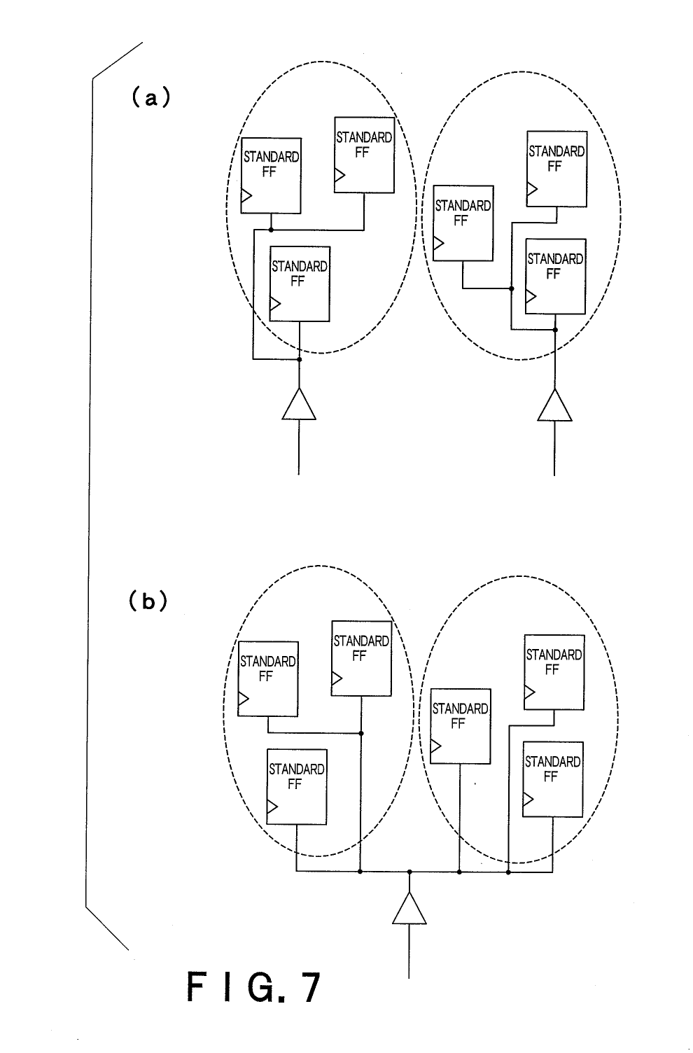

Also, in a case where clusters each containing only standard flip-flop circuits are adjacent to each other as illustrated in FIG. 7(a), the standard flip-flop circuits of the two clusters may be driven by one clock buffer. As the number of clock buffers can be reduced by 1, the power consumption by the clock tree can be reduced further. The removal and sharing of clock buffers are carried out only when input slew requirements are satisfied.

In the above described embodiment, the smaller-size flip-flop circuit of the two-stage inverters 18 and 19 of the clock supply circuit illustrated in FIG. 1(b) is a low power-consumption flip-flop circuit. However, a flip-flop circuit from which the inverters 18 and 19 are eliminated may be used as a low power-consumption flip-flop circuit. FIG. 8 illustrates an example structure of such a flip-flop circuit.

A state holding circuit F11 that holds two states (a logical value “0” and a logical value “1”) is provided in the circuit illustrated in FIG. 8, and inverters V11 through V14 are provided in the state holding circuit F11. The output of the inverter V11 is connected to the input of the inverter V12, to form a storage node MB. The output of the inverter V12 is connected to the input of the inverter V11, to form a storage node M. The storage node MB is connected to the input of the inverter V13, and the storage node M is connected to the input of the inverter V14.

A state holding circuit F12 that holds two states (a logical value “0” and a logical value “1”) is provided in the stage after the state holding circuit F11, to form a master-slave flip-flop. Inverters V3 through V5 are provided in the state holding circuit F12. The output of the inverter V3 is connected to the input of the inverter V4, to form a storage node S. The output of the inverter V4 is connected to the input of the inverter V3, to form a storage node SB. The storage node SB is connected to the input of the inverter V5, to output an output signal Q.

Also, p-channel field effect transistors (hereinafter referred to as the PMOS transistors) M1 and M2, and n-channel field effect transistors (hereinafter referred to as the NMOS transistors) M3 and M4 are provided in this circuit. The drain of the PMOS transistor M1 is connected to the storage node MB, and a data signal D is input to the source of the PMOS transistor M1 via the inverter V1. The drain of the PMOS transistor M2 is connected to the storage node M, and a data inverted signal DB is input to the source of the PMOS transistor M2 via the inverter V2.

The drain of the NMOS transistor M3 is connected to the output of the inverter V13, and the source of the NMOS transistor M3 is connected to the storage node S. The drain of the NMOS transistor M4 is connected to the output of the inverter V14, and the source of the NMOS transistor M4 is connected to the storage node SB. A clock signal CK is input to each gate of the PMOS transistors M1 and M2 and the NMOS transistors M3 and M4.

When the clock signal CK is at the high level, the PMOS transistors M1 and M2 are off, and the NMOS transistors M3 and M4 are on. In the state holding circuit Fl, the storage node MB is maintained at the low level while the storage node M is maintained at the high level, and the storage node MB is maintained at the high level while the storage node M is maintained at the low level.

When the data signal D is input to the inverter V1, the data inverted signal DB is generated and is input to the source of the PMOS transistor M1 and the inverter V2. When the data inverted signal DB is input to the inverter V2, a data signal DBB is generated and is input to the source of the PMOS transistor M2.

When the clock signal CK transits from the high level to the low level, the PMOS transistors M1 and M2 are switched on. At this point, the data inverted signal DB is applied to the storage node MB via the PMOS transistor Ml, the data signal DBB is applied to the storage node M via the PMOS transistor M2, and these states are held by the storage nodes MB and M.

The state of the storage node MB is inverted by the inverter V13, to generate and input the output signal Q1 to the drain of the NMOS transistor M3. The state of the storage node M is also inverted by the inverter V14, to generate and input an output inverted signal QB1 to the drain of the NMOS transistor M4. At this point, the NMOS transistors M3 and M4 are off. Therefore, the state of the output signal Q of the state holding circuit F12 does not change.

When the clock signal CK transits from the low level to the high level, the PMOS transistors M1 and M2 are switched off, and the NMOS transistors M3 and M4 are switched on. As the NMOS transistors M3 and M4 are switched on, the output signal Q1 is applied to the storage node S via the NMOS transistor M3, the output inverted signal QB1 is applied to the storage node SB via the NMOS transistor M4, and these states are held by the storage nodes S and SB.

The state held by the storage node SB is inverted by the inverter V5, to generate the output signal Q.

In a case where the data inverted signal DB is at the high level while the storage node MB is at the low level, the storage node MB can be charged via the PMOS transistor M1. In a case where the data inverted signal DB is at the low level while the storage node MB is at the high level, the data signal DBB is at the high level, and the storage node M is at the low level. Accordingly, the storage node M can be charged via the PMOS transistor M2.

In a case where the output signal Q1 is at the low level while the storage node S is at the high level, the storage node S can be discharged via the NMOS transistor M3. In a case where the output signal Q1 is at the low level while the storage node S is at the high level, the output inverted signal QB1 is at the high level, and the storage node SB is at the low level. The storage node SB can be charged via the NMOS transistor M4.

Further, the data inverted signal DB and the data signal DBB are input to the storage nodes MB and M via the PMOS transistors M1 and M2, respectively. The output signal Q1 and the output inverted signal QB1 are output via the NMOS transistors M3 and M4, respectively. The clock signal CK is then input to the gates of the PMOS transistors M1 and M2 and the gates of the NMOS transistors M3 and M4. Accordingly, the states can be held by the state holding circuit F11, and the states held by the state holding F11 can be output. In this structure, there is no need to provide the clock buffer (the inverters 18 and 19 shown in FIG. 1(b)) for generating a clock inverted signal from the clock signal CK, and the power consumption by the clock buffers can be reduced. In the above described embodiment, the circuit illustrated in FIG. 8 may be used as a low power-consumption flip-flop circuit.

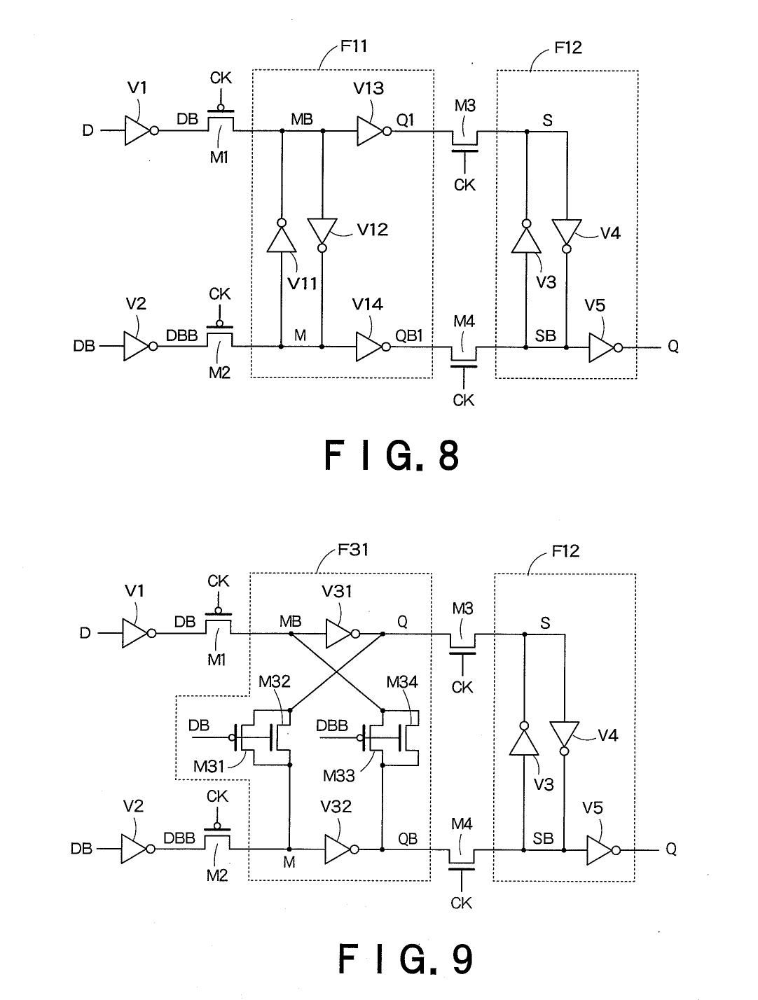

Alternatively, a circuit in which the state holding circuit F11 illustrated in FIG. 8 is replaced with a state holding circuit F31 illustrated in FIG. 9 may be used as a low power-consumption flip-flop circuit. The state holding circuit F31 includes inverters V31 and V32, PMOS transistors M31 and M33, and NMOS transistors M32 and M34.

The output of the inverters V31 is connected to the input of the inverter V32 via the PMOS transistor M31 and the NMOS transistor M32 that are connected in parallel to each other, so that a storage node M is formed. The output of the inverter V32 is connected to the input of the inverter V31 via the PMOS transistor M33 and the NMOS transistor M34 that are connected in parallel to each other, so that a storage node MB is formed.

The data inverted signal DB is input to the gate of the PMOS transistor M31 and the gate of the NMOS transistor M32, and the data signal DBB is input to the gate of the PMOS transistor M33 and the gate of the NMOS transistor M34. The drain of the transistor M1 is connected to the input of the inverter V31, and the drain of the transistor M2 is connected to the inverter V32.

In a case where the data signal D is at the high level, the data inverted signal DB is at the low level, the NMOS transistor M34 is on, and the PMOS transistor M31 is on. In a case where the data signal D is at the low level, on the other hand, the data inverted signal DB is at the high level, the PMOS transistor M33 is on, and the NMOS transistor M32 is on. Therefore, regardless of which state the data signal D is in, the output of the inverter V31 and the input of the inverter V32 are connected to each other, and the output of the inverter V32 and the input of the inverter V31 are connected to each other. Accordingly, in the state holding circuit F31, the storage node MB is maintained at the low level while the storage node M is maintained at the high level, and the storage node MB is maintained at the high level while the storage node M is maintained at the low level.

When the transistors M1 and M2 are switched on, the data inverted signal DB is applied to the storage node MB, and the data signal D is applied to the storage node M. The states of the storage nodes MB and M change with the levels of the data inverted signal DB and the data signal D, and these states are held by the storage nodes MB and M. The states held by the storage nodes MB and M are inverted by the inverters V31 and V32, respectively, and are output as the output signal Q and the output inverted signal QB.

In a case where the PMOS transistors M31 and M33 are on, when a high-level potential VDD is applied to the sources, the drains also have the high-level potential VDD. On the other hand, when a low-level potential VSS is applied to the drains, the sources become higher from the low-level potential VSS by the threshold voltage Vph of the PMOS transistors M31 and M33.

In a case where the NMOS transistors M32 and M34 are on, when a low-level potential VSS is applied to the sources, the drains also have the low-level potential VSS. On the other hand, when a high-level potential VDD is applied to the drains, the sources become lower from the high-level potential VDD by the threshold voltage Vnh of the NMOS transistors M32 and M34.

The storage node MB is at the low level while the data inverted signal DB is at the high level, and storage node M is at the high level while the data signal D is at the low level. In this case, the PMOS transistor M33 and the NMOS transistor M32 are on.

Therefore, when the high-level retention capacity of the storage node M is lowered in the NMOS transistor M32, and the data signal D to be applied to the storage node M is switched to the low level, the state held by the storage node M can be readily switched from the high level to the low level. Also, when the low-level retention capacity of the storage node MB is lowered in the PMOS transistor M33, and the data inverted signal DB to be applied to the storage node MB is switched to the high level, the state held by the storage node MB can be readily switched from the low level to the high level. Accordingly, the source voltage margin that can be operated by this circuit can be widened, and the robustness of the circuit can be improved.

On the other hand, the storage node MB is at the high level while the data inverted signal DB is at the low level, and the storage node M is at the low level while the data signal D is at the high level. At this point, the NMOS transistor M34 and the PMOS transistor M31 are on.

Therefore, when the low-level retention capacity of the storage node M is lowered in the PMOS transistor M31, and the data signal D to be applied to the storage node M is switched to the high level, the state held by the storage node M can be readily switched from the low level to the high level. Also, when the high-level retention capacity of the storage node MB is lowered in the NMOS transistor M34, and the data inverted signal DB to be applied to the storage node MB is switched to the low level, the state held by the storage node MB can be readily switched from the high level to the low level.

By employing the circuit structure illustrated in FIG. 9 as described above, the states held by the storage nodes M and MB can be easily switched, and the operable source voltage margin can be widened. Also, as in the circuit illustrated in FIG. 8, there is no need to prepare the clock buffer (the inverters 18 and 19 shown in FIG. 1(b)) for generating a clock inverted signal from the clock signal CK, and the power consumption by the clock buffers can be reduced.

At least part of the apparatus for designing a semiconductor integrated circuit described in the above embodiments may be implemented in either hardware or software. When implemented in software, a program that realizes at least part of functions of the apparatus for designing a semiconductor integrated circuit may be stored on a recording medium such as a flexible disk or CD-ROM and read and executed by a computer. The recording medium is not limited to a removable recording medium such as a magnetic disk or optical disk, but may be a non-removable recording medium such as a hard disk device or memory.

The program that realizes at least part of the functions of the apparatus for designing a semiconductor integrated circuit may be distributed through a communication line (including wireless communications) such as the Internet. Further, the program may be encrypted, modulated, or compressed to be distributed through a wired line or wireless line such as the Internet or to be distributed by storing the program on a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method for designing a semiconductor integrated circuit, comprising:
placing a plurality of first flip-flop circuits and a plurality of second flip-flop circuits each having a larger amount of delay change than the first flip-flop circuits with respect to a change of a clock signal waveform;
grouping the first flip-flop circuits and the second flip-flop circuits into a plurality of clusters by using an evaluation function having indices that include coordinates of each flip-flop circuit, an input slew constraint, a clock input capacity, and a cell type that indicates whether each flip-flop circuit is one of the first flip-flop circuits or one of the second flip-flop circuits;
assigning a first clock buffer to a first cluster that is formed by the first flip-flop circuits;
assigning a second clock buffer to a second cluster that includes the second flip-flop circuits, the second clock buffer having a larger size than the first clock buffer; and
performing clock wiring in such a manner that an output of the first clock buffer is supplied to the first flip-flop circuits forming the first cluster, and an output of the second clock buffer is supplied to flip-flop circuits forming the second cluster.

2. The method according to claim 1, wherein the second flip-flop circuits in the second cluster are moved into another second cluster, to correct the second cluster to turn into a first cluster.

3. The method according to claim 2, wherein the correction is performed when a value of the evaluation function is equal to or smaller than a predetermined threshold value.

4. The method according to claim 1, wherein the first clock buffers corresponding to a plurality of the first clusters are turned into one first clock buffer.

5. The method according to claim 2, wherein the first clock buffers corresponding to a plurality of the first clusters are turned into one first clock buffer.

6. The method according to claim 3, wherein the first clock buffers corresponding to a plurality of the first clusters are turned into one first clock buffer.

7. A semiconductor integrated circuit comprising:
a plurality of first flip-flop circuits;
a plurality of second flip-flop circuits each having a larger amount of delay change than the first flip-flop circuits with respect to a change in waveform of a clock signal;
a first clock buffer that receives the clock signal; and
a second clock buffer that receives the clock signal and has a larger size than the first clock buffer, wherein
the second clock buffer outputting the clock signal to the first flip-flop circuits and/or the second flip-flop circuits,
the clock signal of the first clock buffer being output to a destination formed by the first flip-flop circuits.

8. The semiconductor integrated circuit according to claim 7, wherein
the first flip-flop circuits and the second flip-flop circuits each have an inverter that inverts the clock signal, and
the inverter of each of the first flip-flop circuits has a larger size than a size of the inverter of each of the second flip-flop circuits.

9. The semiconductor integrated circuit according to claim 7, wherein
the second flip-flop circuits are master-slave flip-flops each including:
a first state holding circuit that holds a logical value “0” and a logical value “1”; and
a second state holding circuit that is provided in a stage after the first state holding circuit, and holds a logical value “0” and a logical value “1”.

10. The semiconductor integrated circuit according to claim 9, wherein
the first state holding circuit includes a plurality of inverters that form a first storage node and a second storage node, and
the second state holding circuit includes a plurality of inverters that form a third storage node and a fourth storage node.

11. The semiconductor integrated circuit according to claim 10, wherein
the first state holding circuit includes first through fourth inverters,
the first storage node is formed by connecting an output of the first inverter to an input of the second inverter,
the second storage node is formed by connecting an output of the second inverter to an input of the first inverter,
the first storage node is connected to an input of the third inverter,
the second storage node is connected to an input of the fourth inverter,
the second state holding circuit includes fifth through seventh inverters,
the third storage node is formed by connecting an output of the fifth inverter to an input of the sixth inverter,
the fourth storage node is formed by connecting an output of the sixth inverter to an input of the fifth inverter, and
the fourth storage node is connected to an input of the seventh inverter.

12. The semiconductor integrated circuit according to claim 11, wherein
the second flip-flop circuits each further include:
an eighth inverter that receives a data signal;
a ninth inverter that receives a data inverted signal;
a first PMOS transistor that has a source connected to an output of the eighth inverter, has a drain connected to the first storage node, and has a gate to receive the clock signal;
a second PMOS transistor that has a source connected to an output of the ninth inverter, has a drain connected to the second storage node, and has a gate to receive the clock signal;
a first NMOS transistor that has a drain connected to an output of the third inverter, has a source connected to the third storage node, and has a gate to receive the clock signal; and
a second NMOS transistor that has a drain connected to an output of the fourth inverter, has a source connected to the fourth storage node, and has a gate to receive the clock signal.

13. The semiconductor integrated circuit according to claim 10, wherein
the first state holding circuit includes a first inverter, a second inverter, a first NMOS transistor, a second NMOS transistor, a first PMOS transistor, and a second PMOS transistor,
the first storage node is formed by connecting an output of the first inverter to an input of the second inverter via the first PMOS transistor and the first NMOS transistor that are connected in parallel to each other,
the second storage node is formed by connecting an output of the second inverter to an input of the first inverter via the second PMOS transistor and the second NMOS transistor that are connected in parallel to each other,
a data inverted signal is input to gates of the first PMOS transistor and the first NMOS transistor,
a data signal is input to gates of the second PMOS transistor and the second NMOS transistor,
the second state holding circuit includes third through fifth inverters,
the third storage node is formed by connecting an output of the third inverter to an input of the fourth inverter,
the fourth storage node is formed by connecting an output of the fourth inverter to an input of the third inverter, and
the fourth storage node is connected to an input of the fifth inverter.

14. The semiconductor integrated circuit according to claim 13, wherein
the second flip-flop circuits each further include:
a sixth inverter that receives the data signal;
a seventh inverter that receives the data inverted signal;
a third PMOS transistor that has a source connected to an output of the sixth inverter, has a drain connected to the first storage node, and has a gate to receive the clock signal;
a fourth PMOS transistor that has a source connected to an output of the seventh inverter, has a drain connected to the second storage node, and has a gate to receive the clock signal;
a third NMOS transistor that has a drain connected to the output of the first inverter, has a source connected to the third storage node, and has a gate to receive the clock signal; and
a fourth NMOS transistor that has a drain connected to the output of the second inverter, has a source connected to the fourth storage node, and has a gate to receive the clock signal.

15. A computer readable recording medium storing a program for designing a semiconductor integrated circuit, the program being executed to cause a computer to:
place a plurality of first flip-flop circuits and a plurality of second flip-flop circuits each having a larger amount of delay change than the first flip-flop circuits with respect to a change of a clock signal waveform;
group the first flip-flop circuits and the second flip-flop circuits into a plurality of clusters by using an evaluation function having indices that include coordinates of each flip-flop circuit, an input slew constraint, a clock input capacity, and a cell type that indicates whether each flip-flop circuit is one of the first flip-flop circuits or one of the second flip-flop circuits;
assign a first clock buffer to a first cluster that is formed by the first flip-flop circuits, and assign a second clock buffer to a second cluster that includes the second flip-flop circuits, the second clock buffer having a larger size than the first clock buffer; and
perform clock wiring in such a manner that an output of the first clock buffer is supplied to the first flip-flop circuits forming the first cluster, and an output of the second clock buffer is supplied to flip-flop circuits forming the second cluster.

16. The computer readable recording medium according to claim 15, wherein the design program causes the computer to move the second flip-flop circuits in the second cluster into another second cluster, to correct the second cluster to turn into a first cluster.

17. The computer readable recording medium according to claim 16, wherein the design program causes the computer to perform the correction when a value of the evaluation function is equal to or smaller than a predetermined threshold value.

18. The computer readable recording medium according to claim 15, wherein the design program causes the computer to turn the first clock buffers corresponding to a plurality of the first clusters into one first clock buffer.

19. The computer readable recording medium according to claim 16, wherein the design program causes the computer to turn the first clock buffers corresponding to a plurality of the first clusters into one first clock buffer.

20. The computer readable recording medium according to claim 17, wherein the design program turns the first clock buffers corresponding to a plurality of the first clusters into one first clock buffer.
